(19) United States
(12) Patent Application Publication
(10) Pub. No.: US 2015/0199134 A1
(43) Pub. Date: Jul. 16, 2015

(54) SYSTEM AND METHOD FOR RESOLVING DRAM PAGE CONFLICTS BASED ON MEMORY ACCESS PATTERNS

(71) Applicant: QUALCOMM INCORPORATED, San Diego, CA (US)

(72) Inventors: MRIGANKA MONDAL, SAN DIEGO, CA (US); HAW-JING LO, SAN DIEGO, CA (US)

(73) Assignee: QUALCOMM INCORPORATED, San Diego, CA (US)

(21) Appl. No.: 14/172,173

(22) Filed: Feb. 4, 2014

Related U.S. Application Data
(60) Provisional application No. 61/926,207, filed on Jan. 10, 2014.

(51) Int. Cl. G06F 3/06; G06F 12/06; G11C 7/10

(52) U.S. Cl. CPC G06F 3/0611; G06F 3/0655; G06F 3/0673; G11C 7/1072; G06F 12/0607; G06F 2212/652

(57) ABSTRACT

Systems, methods, and computer programs are disclosed for managing access requests to a DRAM memory device. One embodiment includes receiving memory access pattern data for at least one of a plurality of memory clients prior to a corresponding memory transaction with a DRAM memory device. Next, it is determined, based on the received memory access pattern data, that a future transaction of a first of the plurality of memory clients may create a future page conflict with a current transaction of a second of the plurality of memory clients. The future page conflict is then resolved by interleaving access to an associated bank in the DRAM memory device by the first and second memory clients according to the received memory access pattern data.

### CROSS-REFERENCE TO RELATED APPLICATION

This application claims the benefit of the priority of U.S. Provisional Patent Application Ser. No. 61/926,207 entitled “System and Method for Resolving DRAM Page Conflicts Based on Memory Access Patterns Provided by Memory Clients” and filed on Jan. 10, 2014, which is hereby incorporated by reference in its entirety.

### DESCRIPTION OF THE RELATED ART

Dynamic random access memory (DRAM), such as double data rate (DDR) type memory, is used in various computing devices (e.g., personal computers, laptops, notebooks, video game consoles, portable computing devices, mobile phones, etc.). Such devices typically include a system on a chip (SoC) comprising a memory controller in communication with one or more memory clients (e.g., central processing unit(s) (CPUs), graphics processing unit(s) (GPU), digital signal processor(s) (DSPs), etc.) for controlling read or write requests to the DDR memory. In conventional memory systems, when concurrent memory clients attempt to make DDR read or write requests, the memory controller grants memory access based on, for example, priority of the memory client and the time of the access request.

Concurrent workload situations can be problematic. For example, when one memory client is trying to make a large data transaction, a different memory client with higher priority can create a page conflict situation in the DDR memory, which forces the memory controller to reprioritize the large data transaction with a relatively smaller data transaction. As known in the art, a DDR memory device may comprise a plurality of banks. A page conflict arises due to the fact DDR memory is configured such that only a single page can be accessed in a bank at any given time. Therefore, in the concurrent use situation, the memory controller suspends the large data transaction with a “page close” operation and initiates the higher priority transaction with a “page open” operation. When the smaller data transaction is completed, the memory controller performs another “page close” and resumes the suspended transaction with another “page open” operation.

While it may be advantageous to enforce priority-based DDR access, managing page conflicts can adversely impact the efficiency and power savings of memory controller operation due to the increased likelihood of page open/close operations. Accordingly, there remains a need in the art for improved systems and methods for minimizing page conflict situations.

### SUMMARY OF THE DISCLOSURE

Systems, methods, and computer programs are disclosed for managing access requests to a DRAM memory device. One embodiment is a method comprising: a receiving memory access pattern data for at least one of a plurality of memory clients prior to a corresponding memory transaction with a DRAM memory device; determining, based on the received memory access pattern data, that a future transaction of a first of the plurality of memory clients will create a future page conflict with a current transaction of a second of the plurality of memory clients; and resolving the future page conflict by interleaving access to an associated bank in the DRAM memory device by the first and second memory clients according to the received memory access pattern data.

Another embodiment is system for managing access requests to a DRAM memory device. One such system comprises a DRAM memory, a plurality of memory clients, and a memory controller. The DRAM memory device comprises a plurality of banks. The memory clients are in communication with the memory controller, which controls access to the DRAM memory device. The memory clients are configured to provide memory access pattern data to the memory controller. The memory controller is configured to determine, based on the memory access pattern data from one or more of the memory clients, that a future transaction of a first of the plurality of memory clients will create a future page conflict with a current transaction of a second of the plurality of memory clients.

### BRIEF DESCRIPTION OF THE DRAWINGS

In the Figures, like reference numerals refer to like parts throughout the various views unless otherwise indicated. For reference numerals with letter character designations such as “102A” or “102B”, the letter character designations may differentiate two like parts or elements present in the same Figure. Letter character designations for reference numerals may be omitted when it is intended that a reference numeral to encompass all parts having the same reference numeral in all Figures.

FIG. 1 is a block diagram of an embodiment of a system for enabling a memory controller to resolve page conflicts according to memory access pattern data provided by one or more memory clients.

FIG. 2 is a flow chart illustrating an embodiment of a method implemented in the system of FIG. 1 for resolving page conflicts according to memory access pattern data provided by one or more memory clients.

FIG. 3 is a data legend for the timing diagrams illustrated in FIGS. 4 & 5.

FIG. 4 is a timing diagram illustrating one embodiment of a method implemented by the memory controller of FIG. 1 for resolving page conflicts associated with a periodic traffic stream and a non-periodic, priority traffic scheme.

FIG. 5 is a timing diagram illustrating another embodiment of a method implemented by the memory controller of FIG. 1 for resolving page conflicts associated with two periodic traffic streams.

FIG. 6 is a block diagram illustrating an exemplary portable computing device for implementing the system of FIG. 1.

### DETAILED DESCRIPTION

The word “exemplary” is used herein to mean “serving as an example, instance, or illustration.” Any aspect described herein as “exemplary” is not necessarily to be construed as preferred or advantageous over other aspects.

In this description, the term “application” may also include files having executable content, such as: object code, scripts, byte code, markup language files, and patches. In addition, an “application” referred to herein, may also include files that are not executable in nature, such as documents that may need to be opened or other data files that need to be accessed.

The term “content” may also include files having executable content, such as: object code, scripts, byte code, markup language files, and patches. In addition, “content” referred to herein, may also include files that are not executable in nature, such as documents that may need to be opened or other data files that need to be accessed.

As used in this description, the terms “component,” “database,” “module,” “system,” and the like are intended to refer to a computer-related entity, either hardware, firmware, a combination of hardware and software, software, or software in execution. For example, a component may be, but is not limited to being, a process running on a processor, a processor, an object, an executable, a thread of execution, a program, and/or a computer. By way of illustration, both an application running on a computing device and the computing device may be a component. One or more components may reside within a process and/or thread of execution, and a component may be localized on one computer and/or distributed between two or more computers. In addition, these components may execute from various computer readable media having various data structures stored thereon. The components may communicate by way of local and/or remote processes such as in accordance with a signal having one or more data packets (e.g., data from one component interacting with another component in a local system, distributed system, and/or across a network such as the Internet with other systems by way of the signal).

In this description, the terms “communication device,” “wireless device,” “wireless telephone”, “wireless communication device,” and “wireless handset” are used interchangeably. With the advent of third generation (“3G”) wireless technology and four generation (“4G”), greater bandwidth availability has enabled more portable computing devices with a greater variety of wireless capabilities. Therefore, a portable computing device may include a cellular telephone, a pager, a PDA, a smartphone, a navigation device, or a hand-held computer with a wireless connection or link.

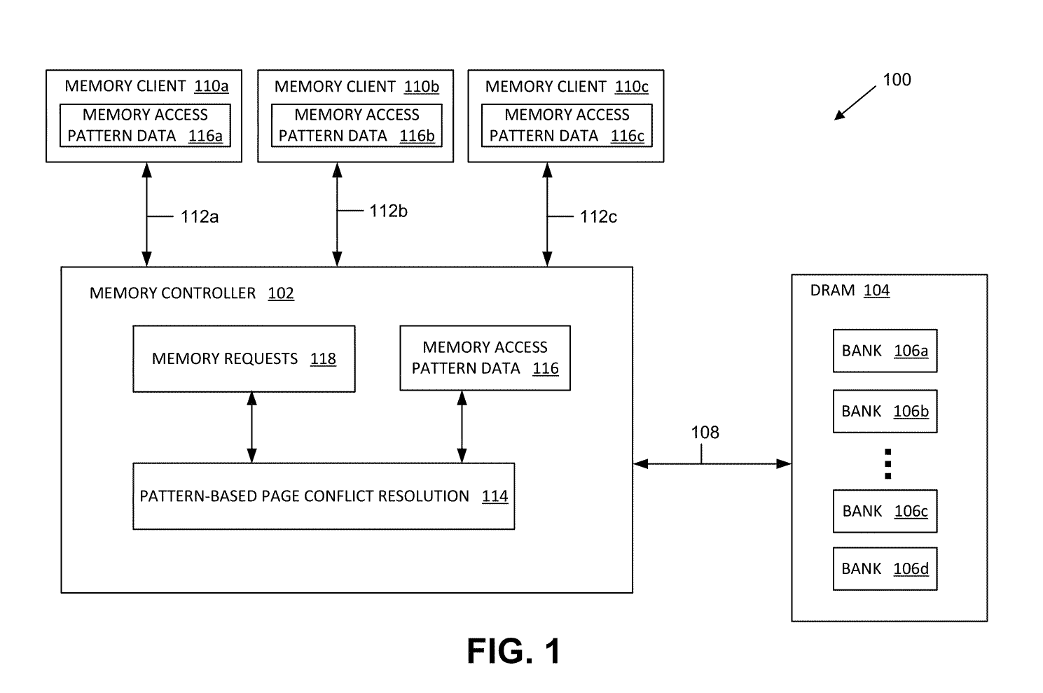

FIG. 1 illustrates a system 100 for improving the efficiency and power conservation of a memory controller 102 by resolving page conflicts associated with a DRAM memory device 104 based on advance or prior knowledge of memory access patterns of one or more memory clients 110. The system 100 may be implemented in any computing device, including a personal computer, a workstation, a server, a portable computing device (PCD), such as a cellular telephone, a portable digital assistant (PDA), a portable game console, a palmtop computer, or a tablet computer.

As illustrated in FIG. 1, the system 100 comprises a memory controller 102, a plurality of memory clients 110a, 110b and 110c, and a DRAM memory system 104. The memory clients 110 may comprise one or more processors or other clients that request read/write access to DRAM memory system 104. In an embodiment, memory clients 110a, 110b and 110c comprise a central processing unit (CPU), a graphics processing unit (GPU), and a digital signal processor (DSP), respectively. Memory clients 110a, 110b, and 110c communicate with memory controller 102 via interfaces 112a, 112b, and 112c, respectively. The memory controller 102 is coupled to DRAM memory system 104 via interface 108.

It should be appreciated that one or more of the components illustrated in FIG. 1 may reside on a system on chip (SoC) coupled to DRAM memory system 104. As known in the art, DRAM memory system 104 comprises a plurality of banks 106a-106d of memory. In an embodiment, DRAM memory system 104 comprises double data rate (DDR) type memory. Each bank 106 includes multiple memory elements each configured to store one or more bits of data. The memory elements within each bank may be organized into pages. For example, in a memory device that is addressable by rows and columns, each page may include a row of memory elements included in a particular bank. As described above, a page conflict occurs when concurrent workloads attempt to access the same bank 106 because only one page per bank 106 can be accessed at a time.

As further illustrated in FIG. 1, the memory controller 102 comprises a pattern-based page conflict resolution component 114, which generally comprises logic for resolving page conflicts based on advance or prior knowledge of the memory access patterns of the memory clients 110. Each of memory clients 110a, 110b, and 110c may be configured to determine and provide memory access pattern data 116a, 116b, and 116, respectively, to the memory controller 102. The memory access pattern data 116 may be provided to the memory controller 102 prior to memory requests 118. It should be appreciated that the memory access pattern data 116 may comprise any suitable data that defines a periodic traffic stream or otherwise represents a model of an access pattern, including, for example, a transaction frequency and a transaction duration. As described below in more detail, the data may also include a latency tolerance specifying an amount of time that a transaction may be delayed during an interleave procedure. The memory access pattern data 116 may be provided by the corresponding memory client 110, or otherwise, via the same or different interface(s) than the memory requests 118 or via one or more side channels.

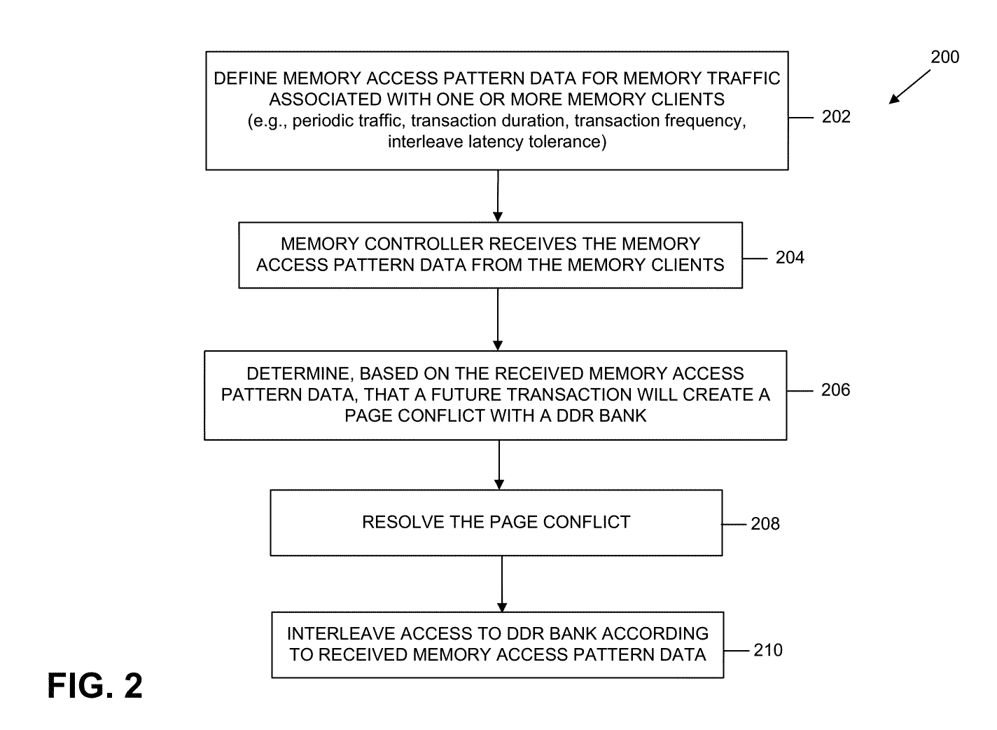

FIG. 2 illustrates an embodiment of a method 200 that may be implemented by the system 100 for resolving page conflicts during concurrent workloads of two more memory clients 110. At block 202, one or more of the memory clients 110 may determine, track, or otherwise define memory access pattern data 116 for its associated memory traffic. The memory access pattern data 116 may comprise any of the following or other types of data for defining a periodic traffic stream: a transaction duration, a transaction frequency, an interleave latency tolerance or delay threshold, and/or any other data that may define a memory access pattern. It should be appreciated that the memory clients 110 or any external logic may determine the memory access pattern data 116. At block 204, the memory controller 102 receives the memory access pattern data 116 from at least one of a plurality of memory clients 110. As mentioned above, the memory access pattern data 116 may be provided via the same interface 112 as memory requests 118 or an alternative interface. At block 206, the page conflict resolution component 114 may access the memory access pattern data 116 and determine whether a future transaction of one of the memory clients 110 will create a future page conflict associated with one of the banks 106. For example, based on the memory access pattern data 116, the page conflict resolution component 118 may determine that a future transaction of a memory client 110a (e.g., a CPU) will create a future page conflict with a current transaction of another memory client 110b (e.g., a GPU). At blocks 208 and 210, the memory controller 110 resolves the future page conflict by, for example, interleaving access to the associated bank 106 by the memory clients 110a and 110b according to the memory access pattern data 116. In an embodiment, access may be interleaved by, for example, delaying one or more of the memory clients 110 up to a maximum latency tolerance, as described below in more detail. The maximum latency tolerance may be generated by any suitable component in system 100 (e.g., memory controller 102, memory clients 110, etc.) and provided to pattern-based page conflict resolution component 114.

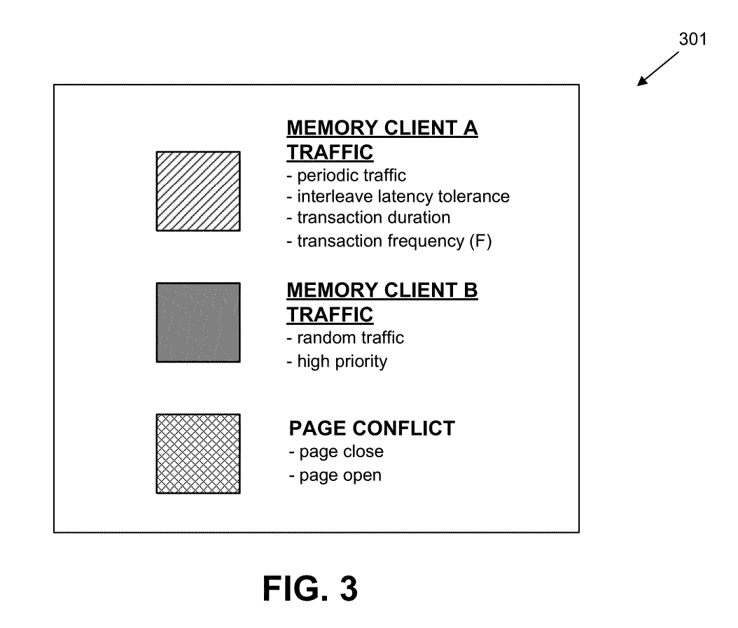

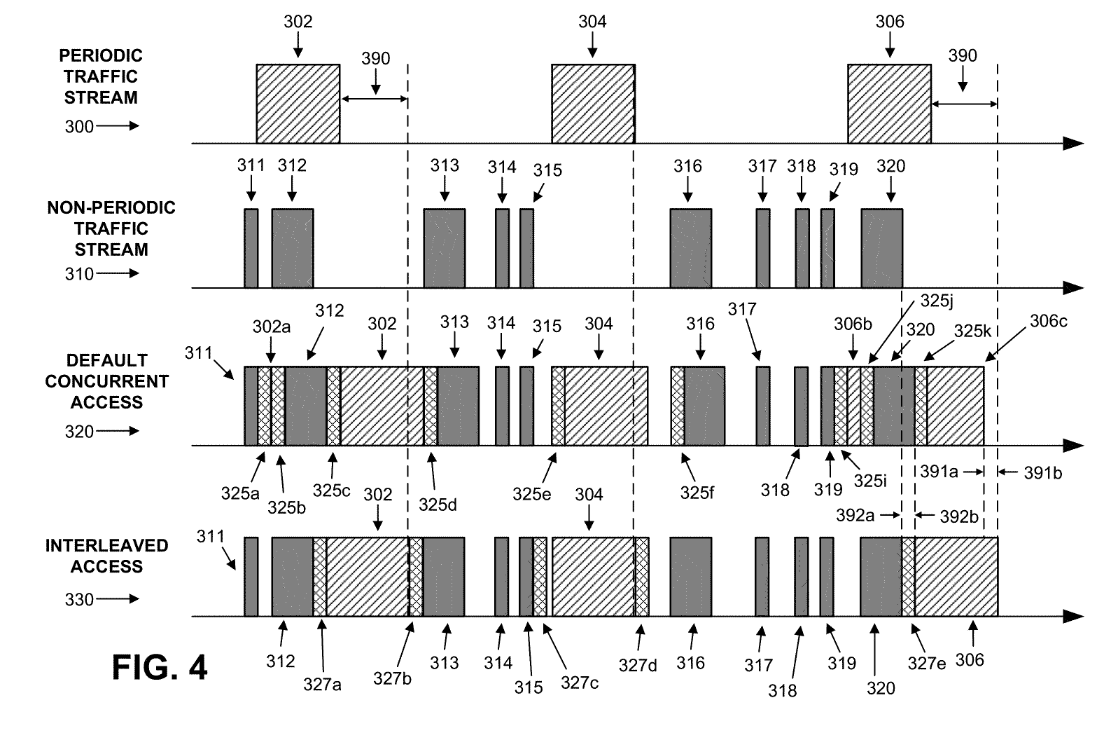

One of ordinary skill in the art will appreciate that the page conflict resolution component 114 may be configured to minimize the number of page close and page open operations used to handle concurrent workloads from one or more periodic traffic streams. FIGS. 4 & 5 illustrate two exemplary embodiments for interleaving memory access in a concurrent workload situation involving traffic streams associated with a first memory client A and a second memory client B. FIG. 3 is a legend 301 for the data signals in the timing diagrams illustrated in FIGS. 4 & 5. It should be appreciated that alternative interleaving and/or delay schemes and any number of traffic streams may be supported. FIGS. 4 & 5 are merely presented to illustrate general operation of the page conflict resolution component 114 with reference to the two traffic streams. One of ordinary skill in the art will appreciate that the optimization techniques may applied to one or more memory clients 110 with the corresponding transactions being implemented as periodic transactions, non-periodic transactions, or any combination thereof

FIG. 4 illustrates an embodiment of a method for resolving page conflicts associated with a periodic traffic stream 300 (memory client A) and a non-periodic, priority traffic stream 310 (memory client B). Periodic traffic stream 300 comprises three transactions 302, 304, and 306 having a fixed transaction duration and transaction frequency. It should be appreciated that periodic traffic stream 300 may be defined by memory access pattern data 116 (e.g., the transaction duration, the transaction frequency, and a latency tolerance), which may be provided to the memory controller 102 before the actual memory access requests 118. Non-periodic traffic stream 310 comprises random priority transactions 311-320. As further illustrated in FIG. 4, periodic traffic stream 300 may include a time duration 390 until a frame boundary represented by the vertical dashed lines.

A default concurrent access mode of operation (similar to conventional solutions) is illustrated in timing diagram 320. In this mode of operation, priority is given to transactions 311-320 without regard to page conflicts. Transactions 302, 304, and 306 may be granted access 300 when available. Referring to timing diagram 320, the memory controller 102 may grant access as follows:
(1) priority transaction 311;
(2) page open/close 325a;
(3) start of periodic transaction 302a
(4) page open/close 325b;
(5) priority transaction 312;
(6) page open/close 325c;
(7) second portion of periodic transaction 302b;
(8) page open/close 325d;
(9) priority transaction 313;
(10) priority transaction 314;
(11) priority transaction 315;
(12) page open/close 325e;
(13) periodic transaction 304;
(14) page open/close 325f;
(15) priority transaction 316;
(16) priority transaction 317;
(17) priority transaction 318;
(18) priority transaction 319;
(19) page open/close 325i;
(20) a first portion of periodic transaction 306a;
(21) page open/close 325j;
(22) priority transaction 320;
(23) page open/close 325k;
(24) a second portion of periodic transaction 306b.

In contrast to the conventional mode of operation, timing diagram 330 illustrates an embodiment for resolving page conflicts by interleaving the priority transactions 311-320 and the periodic transactions 302, 304, and 306 based on the memory access pattern data 116 defining the periodic traffic stream 300. In this embodiment, the memory controller 102 is configured to minimize page open/close operations while giving priority to priority transactions 311-320. Referring to timing diagram 330, the memory controller 102 may interleave access as follows:
(1) priority transaction 311;
(2) priority transaction 312;
(3) page open/close 327a;
(4) periodic transaction 302;
(5) page open/close 327b;
(6) priority transaction 313;
(7) priority transaction 314;
(8) priority transaction 315;
(9) page open/close 327c;
(10) periodic transaction 304;
(11) page open/close 327d;
(12) priority transaction 316;
(13) priority transaction 317;
(14) priority transaction 318;
(15) priority transaction 319;
(16) priority transaction 320;
(17) page open/close 327e;
(18) periodic transaction 306.

One of ordinary skill in the art will appreciate that by interleaving access as illustrated in FIG. 4, the memory controller 102 reduces the number of page open/close operations, thereby improving efficiency and conserving power.

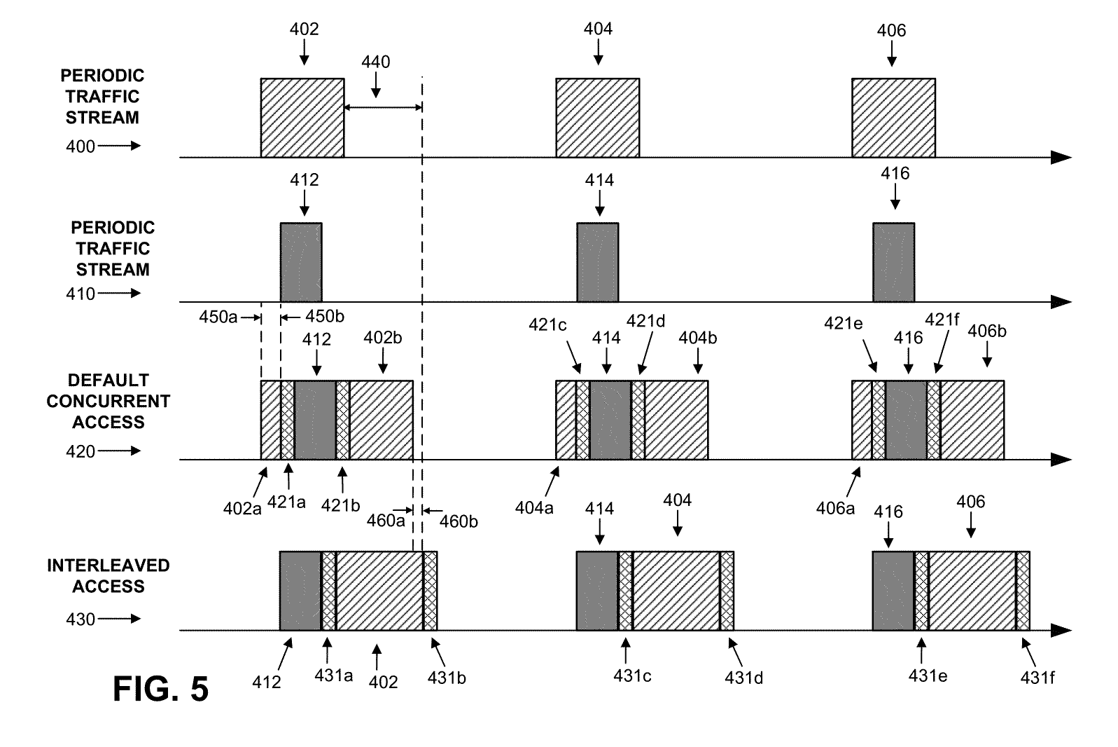

FIG. 5 illustrates another embodiment of a method for resolving page conflicts associated with a two periodic traffic streams 400 and 410. Periodic traffic stream 400 comprises three transactions 402, 404, and 406 having a fixed transaction duration and transaction frequency. Periodic traffic stream 410 comprises three priority transactions 412, 414, and 416 having a fixed transaction duration and transaction frequency. Periodic traffic streams 400 and 410 may be defined by memory access pattern data 116 comprising transaction duration, transaction frequency, and a latency tolerance, which may be provided to the memory controller 102 before the actual memory access requests 118. Periodic traffic stream 400 may include a time duration 440 until a frame boundary represented by the vertical dashed line.

As illustrated in FIG. 5 (timing diagram 420), the memory controller 102 may grant access in the default concurrent access mode of operation as follows:
(1) a first portion of periodic transaction 402a;
(2) page open/close 421a;
(3) priority transaction 412;
(4) page open/close 421b;
(5) a second portion of periodic transaction 402b;
(6) a first portion of periodic transaction 404a;
(7) page open/close 421c;
(8) priority transaction 414;
(9) page open/close 421d;
(10) a second portion of periodic transaction 404b;
(11) a first portion of periodic transaction 406a;
(12) page open/close 421e;
(13) priority transaction 416;
(14) page open/close 421f;
(15) a second portion of periodic transaction 406b

Timing diagram 430 illustrates an embodiment for resolving page conflicts by interleaving the priority transactions 412, 414, and 416 and the periodic transactions 402, 404, and 406 according to the respective memory access pattern data 116 defining the periodic traffic streams 400 and 410. In this embodiment, the memory controller 102 resolves future page conflicts while giving priority to priority transactions 412, 414, and 416 and avoiding the need to suspend and resume periodic traffic stream 400. The memory controller 102 may interleave access as follows:
(1) priority transaction 412;
(2) page open/close 431a;
(3) periodic transaction 402;
(4) patent open/close 431b;
(5) priority transaction 414;
(6) page open/close 431c;
(7) periodic transaction 404;
(8) page open/close 431d;
(9) priority transaction 416;
(10) page open/close 431e;
(11) periodic transaction 406;
(12) page open/close 431f.

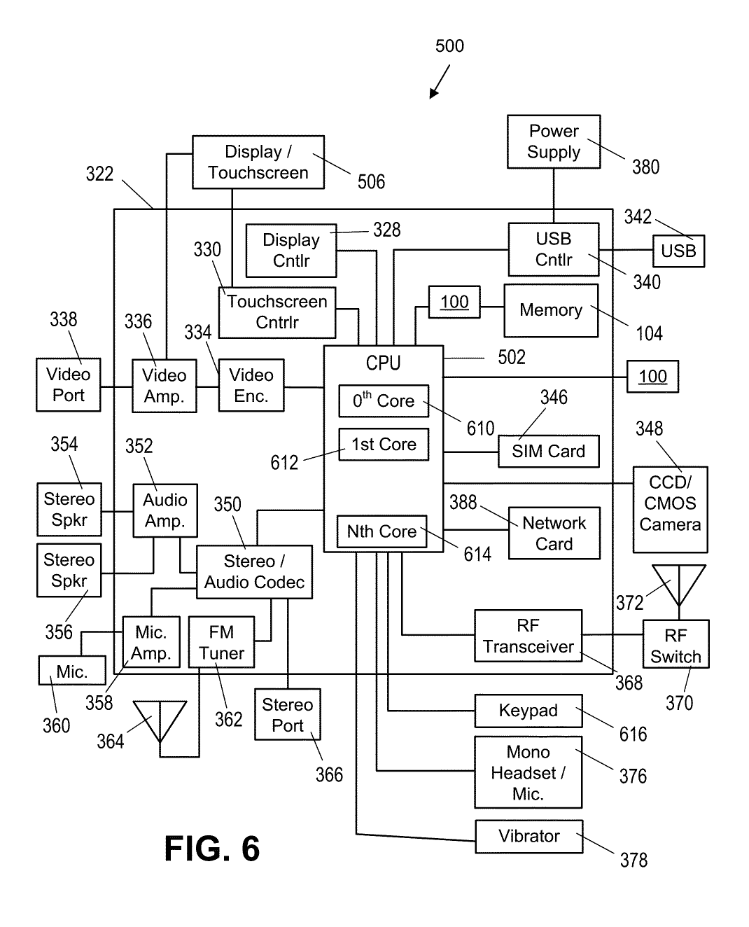

As mentioned above, the system 100 may be incorporated into any desirable computing system. FIG. 6 illustrates the system 100 incorporated in an exemplary portable computing device (PCD) 500. It will be readily appreciated that certain components of the system 100 are included on the SoC 322 (FIG. 6) while other components (e.g., the DRAM memory 104) may be external components coupled to the SoC 322. The SoC 322 may include a multicore CPU 502. The multicore CPU 502 may include a zeroth core 610, a first core 612, and an Nth core 614. One of the cores may comprise, for example, a graphics processing unit (GPU) with one or more of the others comprising the CPU.

A display controller 328 and a touch screen controller 330 may be coupled to the CPU 502. In turn, the touch screen display 108 external to the on-chip system 322 may be coupled to the display controller 1206 and the touch screen controller 330.

FIG. 6 further shows that a video encoder 334, e.g., a phase alternating line (PAL) encoder, a sequential color a memoire (SECAM) encoder, or a national television system(s) committee (NTSC) encoder, is coupled to the multicore CPU 502. Further, a video amplifier 336 is coupled to the video encoder 334 and the touch screen display 506. Also, a video port 338 is coupled to the video amplifier 336. As shown in FIG. 6, a universal serial bus (USB) controller 340 is coupled to the multicore CPU 502. Also, a USB port 342 is coupled to the USB controller 340. Memory 104 and a subscriber identity module (SIM) card 346 may also be coupled to the multicore CPU 502. Memory 104 may reside on the SoC 322 or be coupled to the SoC 322.

Further, as shown in FIG. 6, a digital camera 348 may be coupled to the multicore CPU 502. In an exemplary aspect, the digital camera 348 is a charge-coupled device (CCD) camera or a complementary metal-oxide semiconductor (CMOS) camera.

As further illustrated in FIG. 6, a stereo audio coder-decoder (CODEC) 350 may be coupled to the multicore CPU 502. Moreover, an audio amplifier 352 may coupled to the stereo audio CODEC 350. In an exemplary aspect, a first stereo speaker 354 and a second stereo speaker 356 are coupled to the audio amplifier 352. FIG. 6 shows that a microphone amplifier 358 may be also coupled to the stereo audio CODEC 350. Additionally, a microphone 360 may be coupled to the microphone amplifier 358. In a particular aspect, a frequency modulation (FM) radio tuner 362 may be coupled to the stereo audio CODEC 350. Also, an FM antenna 364 is coupled to the FM radio tuner 362. Further, stereo headphones 366 may be coupled to the stereo audio CODEC 350.

FIG. 6 further illustrates that a radio frequency (RF) transceiver 368 may be coupled to the multicore CPU 502. An RF switch 370 may be coupled to the RF transceiver 368 and an RF antenna 372. As shown in FIG. 6, a keypad 616 may be coupled to the multicore CPU 502. Also, a mono headset with a microphone 376 may be coupled to the multicore CPU 502. Further, a vibrator device 378 may be coupled to the multicore CPU 502.

FIG. 6 also shows that a power supply 380 may be coupled to the on-chip system 322. In a particular aspect, the power supply 380 is a direct current (DC) power supply that provides power to the various components of the PCD 500 that requires power. Further, in a particular aspect, the power supply is a rechargeable DC battery or a DC power supply that is derived from an alternating current (AC) to DC transformer that is connected to an AC power source.

FIG. 6 further indicates that the PCD 500 may also include a network card 388 that may be used to access a data network, e.g., a local area network, a personal area network, or any other network. The network card 388 may be a Bluetooth network card, a WiFi network card, a personal area network (PAN) card, a personal area network ultra-low-power technology (PeANUT) network card, a television/cable/satellite tuner, or any other network card well known in the art. Further, the network card 388 may be incorporated into a chip, i.e., the network card 388 may be a full solution in a chip, and may not be a separate network card 388.

As depicted in FIG. 6, the touch screen display 506, the video port 338, the USB port 342, the camera 348, the first stereo speaker 354, the second stereo speaker 356, the microphone 360, the FM antenna 364, the stereo headphones 366, the RF switch 370, the RF antenna 372, the keypad 374, the mono headset 376, the vibrator 378, and the power supply 380 may be external to the on-chip system 322.

It should be appreciated that one or more of the method steps described herein may be stored in the memory as computer program instructions, such as the modules described above. These instructions may be executed by any suitable processor in combination or in concert with the corresponding module to perform the methods described herein.

Certain steps in the processes or process flows described in this specification naturally precede others for the invention to function as described. However, the invention is not limited to the order of the steps described if such order or sequence does not alter the functionality of the invention. That is, it is recognized that some steps may performed before, after, or parallel (substantially simultaneously with) other steps without departing from the scope and spirit of the invention. In some instances, certain steps may be omitted or not performed without departing from the invention. Further, words such as “thereafter”, “then”, “next”, etc. are not intended to limit the order of the steps. These words are simply used to guide the reader through the description of the exemplary method.

Additionally, one of ordinary skill in programming is able to write computer code or identify appropriate hardware and/or circuits to implement the disclosed invention without difficulty based on the flow charts and associated description in this specification, for example.

Therefore, disclosure of a particular set of program code instructions or detailed hardware devices is not considered necessary for an adequate understanding of how to make and use the invention. The inventive functionality of the claimed computer implemented processes is explained in more detail in the above description and in conjunction with the Figures which may illustrate various process flows.

In one or more exemplary aspects, the functions described may be implemented in hardware, software, firmware, or any combination thereof. If implemented in software, the functions may be stored on or transmitted as one or more instructions or code on a computer-readable medium. Computer-readable media include both computer storage media and communication media including any medium that facilitates transfer of a computer program from one place to another. A storage media may be any available media that may be accessed by a computer. By way of example, and not limitation, such computer-readable media may comprise RAM, ROM, EEPROM, NAND flash, NOR flash, M-RAM, P-RAM, R-RAM, CD-ROM or other optical disk storage, magnetic disk storage or other magnetic storage devices, or any other medium that may be used to carry or store desired program code in the form of instructions or data structures and that may be accessed by a computer.

Also, any connection is properly termed a computer-readable medium. For example, if the software is transmitted from a website, server, or other remote source using a coaxial cable, fiber optic cable, twisted pair, digital subscriber line (“DSL”), or wireless technologies such as infrared, radio, and microwave, then the coaxial cable, fiber optic cable, twisted pair, DSL, or wireless technologies such as infrared, radio, and microwave are included in the definition of medium.

Disk and disc, as used herein, includes compact disc (“CD”), laser disc, optical disc, digital versatile disc (“DVD”), floppy disk and blu-ray disc where disks usually reproduce data magnetically, while discs reproduce data optically with lasers. Combinations of the above should also be included within the scope of computer-readable media.

Alternative embodiments will become apparent to one of ordinary skill in the art to which the invention pertains without departing from its spirit and scope. Therefore, although selected aspects have been illustrated and described in detail, it will be understood that various substitutions and alterations may be made therein without departing from the spirit and scope of the present invention, as defined by the following claims.

What is claimed is:

1. A method for managing access requests to a DRAM memory device, the method comprising:
receiving memory access pattern data for at least one of a plurality of memory clients prior to a corresponding memory transaction with a DRAM memory device;
determining, based on the received memory access pattern data, that a future transaction of a first of the plurality of memory clients will create a future page conflict with a current transaction of a second of the plurality of memory clients; and
resolving the future page conflict by interleaving access to an associated bank in the DRAM memory device by the first and second memory clients according to the received memory access pattern data.

2. The method of claim 1, wherein the memory access pattern data comprises periodic traffic data comprising one or more of a transaction frequency, a transaction duration, and a latency tolerance.

3. The method of claim 1, wherein the memory access pattern data is provided to a memory controller by one of the first and second memory clients prior to corresponding memory transaction.

4. The method of claim 1, wherein the first memory client comprises a periodic traffic stream and the second memory client comprises a non-periodic, priority traffic stream.

5. The method of claim 1, wherein the interleaving access to the associated bank in the DRAM memory device by the first and second memory clients comprises minimizing a number of page-close-page-open operations.

6. The method of claim 1, wherein the interleaving access to the associated bank in the DRAM memory device by the first and second memory clients comprises delaying one of the first and second memory clients based on a latency tolerance.

7. A system for managing access requests to a DRAM memory device, the system comprising:
a DRAM memory device comprising a plurality of banks;
a plurality of memory clients in communication with a memory controller for controlling access to the DRAM memory device, the memory clients configured to provide memory access pattern data to the memory controller; and
the memory controller configured to determine, based on the memory access pattern data for one or more of the memory clients, that a future transaction of a first of the plurality of memory clients will create a future page conflict with a current transaction of a second of the plurality of memory clients.

8. The system of claim 7, wherein the memory controller is further configured to resolve the future page conflict by interleaving access to an associated bank in the DRAM memory device by the first and second memory clients according to the received memory access pattern data.

9. The system of claim 8, wherein the memory controller is further configured to minimize a number of page-close-page-open operations.

10. The system of claim 7, wherein the memory access pattern data comprises periodic traffic data comprising one or more of a transaction frequency, a transaction duration, and a latency tolerance.

11. The system of claim 7, wherein the memory access pattern data defines a periodic traffic stream.

12. The system of claim 7, wherein the first memory client comprises a periodic traffic stream and the second memory client comprises a non-periodic, priority traffic stream.

13. The system of claim 7, wherein the memory clients comprise one or more of a central processing unit, a graphics processing unit, and a digital signal processor.

14. The system of claim 1, wherein the DRAM memory device comprises a double data rate (DDR) memory device and the system is implemented in a portable computing device.

15. A computer program embodied in a computer readable medium and executed by a processor, the computer program for managing access requests to a DRAM memory device, the computer program comprising logic configured to:
receive memory access pattern data for at least one of a plurality of memory clients prior to a corresponding memory transaction with a DRAM memory device;
determine, based on the received memory access pattern data, that a future transaction of a first of the plurality of memory clients will create a future page conflict with a current transaction of a second of the plurality of memory clients; and
resolve the future page conflict by interleaving access to an associated bank in the DRAM memory device by the first and second memory clients according to the received memory access pattern data.

16. The computer program of claim 15, wherein the memory access pattern data comprises periodic traffic data comprising one or more of a transaction frequency, a transaction duration, and a latency tolerance.

17. The computer program of claim 15, wherein the first memory client comprises a periodic traffic stream and the second memory client comprises a non-periodic, priority traffic stream.

18. The computer program of claim 15, wherein the interleaving access to the associated bank in the DRAM memory device by the first and second memory clients comprises minimizing a number of page-close-page-open operations.

19. The computer program of claim 15, wherein the DRAM memory device comprises a double data rate (DDR) memory device.

20. The computer program of claim 15, wherein the logic resides in a memory controller in a portable computing device.
